(19) United States
(12) Patent Application Publication
(10) Pub. No.: US 2011/0079507 A1
(43) Pub. Date: Apr. 7, 2011

(54) MANUFACTURING METHOD OF SEMICONDUCTOR ELEMENT

(75) Inventor: Hiroaki KAJI, Ichihara-shi (JP)

(73) Assignee: SHOWA DENKO K.K., Tokyo (JP)

(21) Appl. No.: 12/896,471

(22) Filed: Oct. 1, 2010

(30) Foreign Application Priority Data
Oct. 2, 2009 (JP) 2009-230730
Sep. 28, 2010 (JP) 2010-217176

(51) Int. Cl. C23C 14/34

(52) U.S. Cl. 204/192.1

(57) ABSTRACT

A manufacturing method of a semiconductor element formed by multi-layering on a substrate so as to include an n-type semiconductor and a p-type semiconductor. The method includes a process of sputtering, with a gas including a group V element, at least two targets (a first target 21 and a second target 22) made of group III elements that are different from each other, thereby to form a film of a III-V compound semiconductor on the substrate 110.

### TECHNICAL FIELD

The present invention relates to a manufacturing method of a semiconductor element using a III-V compound semiconductor.

### BACKGROUND ART

A III-V compound semiconductor, especially a semiconductor element using gallium nitride (GaN), aluminum nitride (AlN) or indium nitride (InN) each of which includes nitrogen (N) as a group V element, has been researched not only as a light emitter emitting blue light but also as a high frequency device, a large current device, a photo detector, a solar battery, or the like.

In particular, for a compound semiconductor including at least two of GaN, AlN and InN, the band gap thereof can be controlled in a wide range by varying density of included gallium (Ga), indium (In), aluminum (Al) or the like.

A film of such a compound semiconductor is grown with a method such as the metal organic chemical vapor deposition (MOCVD) method, the molecular beam epitaxy (MBE) method or the hydride vapor phase epitaxy (HVPE) method.

However, in the MOCVD method, crystallinity of a formed film is determined by a relationship between the lattice constant of a substrate and that of the film. Thus, the smaller the mismatch of the lattice constants (the lattice mismatch) is, the better crystallinity the film has. The larger the lattice mismatch is, the worse crystallinity the film has. Accordingly, it is difficult to form a nitride film in which density of gallium (Ga), indium (In) or aluminum (Al), for example, is arbitrarily set.

Furthermore, in the MOCVD method, a substrate needs to be set at a temperature of 1000 degrees C. or the like, for example. Thus, it is difficult to increase density of In, which is easy to deposit at a high temperature.

In contrast, the sputtering (sputter) method is a method in which particles (atoms or molecules) or the like having kinetic energy are made to collide against a substrate. Thus, it is not necessary to set the temperature of the substrate to be high.

Patent Document 1 describes the following method for growing a compound semiconductor: an electrically conductive substrate obtained by evaporating a metal on an optically polished C-plane substrate of sapphire or an optically polished glass is used; at least one of metallic aluminum, metallic gallium and metallic indium is set as a target; direct current bias is applied between the target and the substrate; AlₓGa₁₋ₓN (where 0≦x≦1) or InN, which is a III-V compound semiconductor, is deposited on the substrate as a buffer layer in an atmosphere including a nitrogen gas by the high frequency sputtering method; and next, AlₓGa₁₋ₓN (where 0≦x≦1) or InN, which has the same composition as the buffer layer, is epitaxially grown on the buffer layer.

Patent Document 2 describes the following method for manufacturing a compound film: a target made of a material, such as Ga or Ga—In, having a low melting point is used; when reactive sputtering is conducted, the temperature of the target surface is raised more than the melting point to melt the target; and thereby a growth rate of the compound film to be formed is improved and the amount of nitrogen included in the film is increased, thereby to improve the quality of the film.

### CITATION LIST

### Patent Literature

Patent Document 1: Japanese Patent Application Laid Open Publication No. 60-173829
Patent Document 2: Japanese Patent Application Laid Open Publication No. 2005-272894

### SUMMARY OF INVENTION

### Technical Problem

It is preferable that a film of a compound semiconductor having excellent crystallinity and having an arbitrary composition ratio can be formed on a substrate. In particular, for a film of a compound semiconductor including In, it is preferable that a film of a compound semiconductor having high density of In can be formed.

However, Patent Document 1 shows only formation of a film of InN, and Patent Document 2 shows only formation of a film of GaN using Ga as a target and a film of InGaN using Ga-75% In as a target.

In order to control a band gap in a wide range, it is preferable that films having composition ratios of In in a wider range can be formed.

The present invention provides a method for manufacturing a semiconductor element that uses a film of a compound semiconductor having a composition ratio controlled in a wide range and having excellent crystallinity.

### Solution to Problem

In order to attain the above object, a manufacturing method of a semiconductor element to which the present invention is applied is a manufacturing method of a semiconductor element formed by multi-layering on a substrate so as to include an n-type semiconductor and a p-type semiconductor. The method includes a process of sputtering, with a gas including a group V element, at least two targets made of group III elements that are different from each other, thereby to form a film of a III-V compound semiconductor on the substrate. A semiconductor light emitter, a semiconductor photo detector and the like may be provided as the semiconductor element.

Here, a shield panel can be included between the at least two targets made of the group III elements that are different from each other.

A composition ratio of the compound semiconductor is set by sputtering power supplied to each of the at least two targets made of the group III elements.

The substrate of the semiconductor element is alternately located at each of positions respectively facing the at least two targets, and thereby the film of the compound semiconductor is formed.

The group III elements are indium (In) and gallium (Ga), the group V element is nitrogen (N), and the compound semiconductor is InₓGa₁₋ₓN (where 0<x<1).

The composition ratio x of indium (In) in the III-V compound semiconductor is set, by sputtering power P1 supplied to one of the targets made of the indium (In) and sputtering power P2 supplied to one of the targets made of the gallium (Ga), as follows

x=1.21×P1/(P1+P2).

When the composition ratio x of indium (In) in the compound semiconductor is in a range of not less than 0.7, substrate temperature can be set to be not less than 150 degrees C. and not more than 400 degrees C.

Meanwhile, when the composition ratio x of indium (In) in the compound semiconductor is in a range of not less than 0.3 and less than 0.7, substrate temperature can be set to be more than 400 degrees C. and not more than 800 degrees C.

Furthermore, the substrate is formed of any one of sapphire, silicon carbide (SiC), gallium nitride (GaN), zinc oxide (ZnO), quartz and amorphous solid (glass).

The semiconductor element is any one of a semiconductor light emitter and a semiconductor photo detector.

### ADVANTAGEOUS EFFECTS OF INVENTION

According to the present invention, it is possible to manufacture a semiconductor element that uses a film of a compound semiconductor having a composition ratio controlled in a wide range and having excellent crystallinity.

### BRIEF DESCRIPTION OF DRAWINGS

FIG. 1 is a diagram showing a cross sectional configuration of an example of a sputtering (sputter) apparatus used for a manufacturing method of a semiconductor element to which the exemplary embodiment is applied;

FIG. 2 is a cross sectional view, taken along a line II-II, of the sputtering apparatus shown in FIG. 1;

FIG. 3 is a surface view of the substrate holder of the sputtering apparatus;

FIG. 4 shows a cross sectional structure of a semiconductor light emitter serving as an example of a semiconductor element manufactured by using the sputtering apparatus;

FIG. 5 is a flowchart for explaining a method to form the base layer on the substrates;

FIG. 6 is a table showing a relationship between various manufacturing conditions and evaluation results for examples 1 to 7 and comparative examples 1 and 2;

FIG. 7 is a graph showing peaks of the X-ray diffraction for the examples 1, 4, 6 and 7 and the comparative examples 1 and 2; and

FIG. 8 is a graph showing a relationship between the In composition ratio x and a sputtering power ratio P1(In)/(P1(In)+P2(Ga)) for the examples 1 to 7.

### DESCRIPTION OF EMBODIMENTS

Hereinafter, an exemplary embodiment of the present invention will be described in detail with reference to the accompanying drawings.

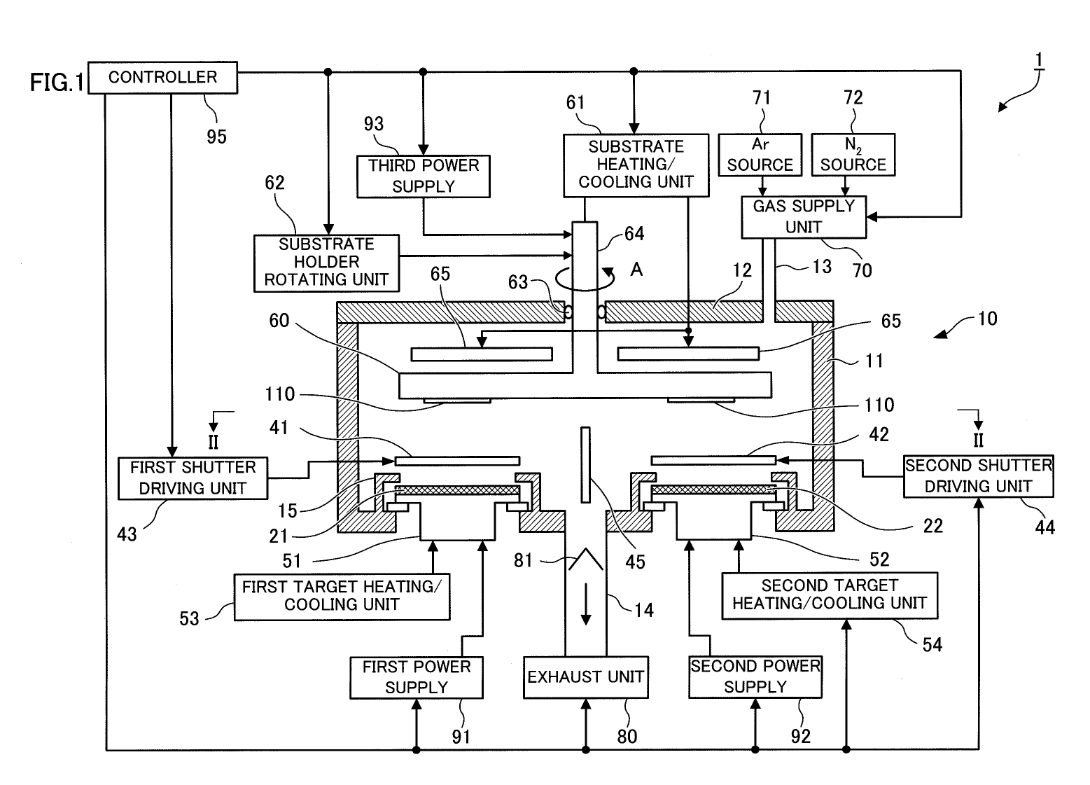

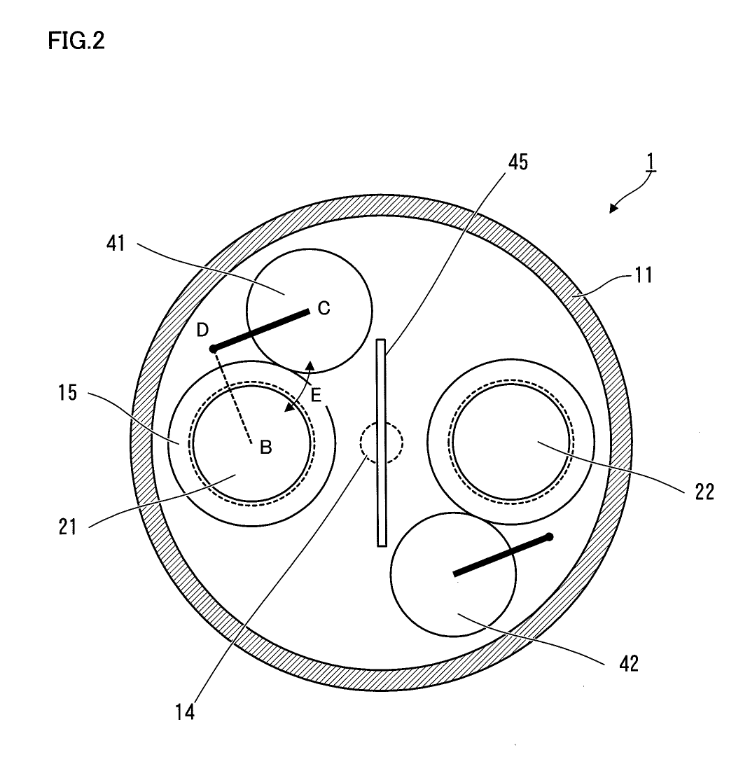

FIG. 1 is a diagram showing a cross sectional configuration of an example of a sputtering (sputter) apparatus 1 used for a manufacturing method of a semiconductor element to which the present exemplary embodiment is applied. FIG. 2 is a cross sectional view, taken along a line II-II, of the sputtering apparatus 1 shown in FIG. 1.

The sputtering apparatus 1 has a structure of a parallel plate type in which substrates 110 and targets (a first target 21 and a second target 22) are arranged so as to face each other, the targets being materials of films to be formed on the substrates 110. Although two targets are provided as multi-targets in the present exemplary embodiment, a larger number of targets may be included. The sputtering apparatus 1 is not limited to the parallel plate type, but may be a carousel type in which a substrate holder of a polygonal cylinder type is used and formation of a film is carried out while the substrate holder rotates around a perpendicular rotation axis.

The sputtering apparatus 1 includes: a chamber 10 that has an inside maintained in a depressurized state, and in which plasma discharge is formed; a first cathode 51 and a second cathode 52 that are installed in the chamber 10 and hold the first target 21 and the second target 22, respectively; and a substrate holder 60 that holds the substrates 110 and rotates the substrates 110 so that the substrates 110 face the first target 21 or the second target 22.

Among these, the chamber 10 has a cylindrical shape, and has an opening facing upward formed therein. In the inside thereof, the chamber 10 includes: a container 11 that contains the first target 21 and the second target 22; and a lid portion 12 that has a disk shape, is attached on an upper portion of the container 11 and holds the substrate holder 60.

The container 11 and the lid portion 12 are formed of metal such as stainless steel. The lid portion 12 is attached so as to be openable and closable with respect to the container 11, and forms the chamber 10 together with the container 11 when closed with respect to the container 11. A seal member such as unillustrated o-ring is attached at a portion where the container 11 and the lid portion 12 face each other.

The container 11 and the lid portion 12 are grounded so as to be a reference of a potential.

At a center portion of the lid portion 12, a through hole for a rotation axis 64 of the substrate holder 60 to penetrate is formed. Between this through hole and the rotation axis 64 of the substrate holder 60, an axis seal 63 formed of an o-ring or the like is provided to hold the substrate holder 60 so as to be rotatable without inflow of the air. The substrate holder 60 is able to rotate around the rotation axis 64 in the direction indicated by an arrow A.

Furthermore, at a position apart from the center portion of the lid portion 12, a through hole is formed to supply a gas from a gas supply unit 70 provided outside to the inside of the chamber 10.

On the other hand, on the bottom surface of the container 11, an exhaust pipe 14 is formed to penetrate the bottom surface, in order to exhaust the chamber 10. The exhaust pipe 14 is provided with an exhaust speed adjusting valve 81 to adjust exhaust speed.

On the bottom surface of the container 11, through holes are provided to attach the first target 21 and the second target 22. The first target 21 and the second target 22 are fixed to target holders respectively provided to the first cathode 51 and the second cathode 52. The target holders and the container 11 are electrically isolated from each other, and fixed to each other through a seal member such as o-ring so that the depressurized state is maintained.

Additionally, shield members 15 are provided that extend from the container 11 to cover peripheral portions of the first target 21 and the second target 22. The shield members 15 are held at a potential of the container 11, and prevents plasma discharge generated at the peripheral portions of the targets (the first target 21 and the second target 22) from causing a constituent material other than the targets (the container 11, the target holders and the like) to be mixed into the films. The shield members 15 do not need to be integrated with the container 11, but may be formed of another member.

Furthermore, on a side surface of the container 11, a through hole (not shown) to observe the inside of the reaction chamber from outside is also formed.

The substrate holder 60 is capable of mounting the substrates 110 so that the surfaces thereof on which the films are formed face downward in FIG. 1.

In a case of high frequency (RF) sputtering, the first cathode 51 and the second cathode 52 include an impedance matching circuit consisting of a coil, a variable condenser and the like that are connected to the target holders, so that high frequency power is efficiently supplied to the targets. Power is supplied to the impedance matching circuit. Meanwhile, in a case of direct current (DC) sputtering, power is directly supplied to the target holders of the first cathode 51 and the second cathode 52.

Alternatively, in a case of a magnetron system where an electron is made to perform magnetron motion by generation of a magnetic field around the targets (the first target 21 and the second target 22) thereby to form high density plasma discharge, the first cathode 51 and/or the second cathode 52 may be provided with a module made of permanent magnet (magnet).

The sputtering apparatus 1 includes a first power supply 91 and a second power supply 92 that supply power to the first target 21 and the second target 22, respectively. Additionally, the sputtering apparatus 1 includes a third power supply 93 that supplies power to the substrate holder 60. The third power supply 93 allows reverse sputtering (reverse sputter) by which ion impact is given to the surfaces of the substrates 110.

As described above, in the case of high frequency sputtering, a high frequency power supply is used for each of these power supplies (the first power supply 91, the second power supply 92 and the third power supply 93). Meanwhile, in the case of direct current sputtering, a direct current power supply is used for each of these power supplies (the first power supply 91, the second power supply 92 and the third power supply 93). Note that a high frequency power supply and a direct current power supply are used in a mixed manner: a high frequency power supply for the first power supply 91, a direct current power supply for the second power supply 92, and the like. These may be selected in accordance with films to be formed.

As described above, the container 11 and the lid portion 12 of the sputtering apparatus 1 are grounded. Thus, a high frequency or direct current voltage is applied between the container 11 and the lid portion 12, and each of the power supplies (the first power supply 91, the second power supply 92 and the third power supply 93).

Additionally, the sputtering apparatus 1 includes a substrate holder rotating unit 62 to rotate the substrate holder 60 around the rotation axis 64. The substrate holder rotating unit 62 is configured by a motor and the like, and is capable of adjusting rotation speed.

Furthermore, the sputtering apparatus 1 includes a substrate heating/cooling unit 61 that controls the temperature of the substrates 110. The substrate heating/cooling unit 61 circulates coolant, such as water, through the hollow inside of the substrate holder 60, thereby to cool the substrates 110. Additionally; the substrate heating/cooling unit 61 heats the substrate holder 60 with a heater 65, such as a halogen lamp, provided between the substrate holder 60 and the lid portion 12, and heats the substrates 110 through the substrate holder 60.

The sputtering apparatus 1 includes the gas supply unit 70 that supplies a gas to the chamber 10 through a supply pipe 13. In the present exemplary embodiment, the gas supply unit 70 supplies a mixed gas of argon supplied from an Ar source 71 and nitrogen, as an example of a group V element, supplied from an N₂ source 72. Since argon is an inert gas, argon and the materials of the targets (the first target 21 and the second target 22) do not produce any compound. However, nitrogen reacts with the materials of the targets (the first target 21 and/or the second target 22), thereby to produce nitride. It is conceivable that the nitride is produced in plasma, comes as particles onto the surfaces of the substrates 110, and adheres thereto.

Sputtering to produce a compound such as nitride is called reactive sputtering.

Furthermore, the sputtering apparatus 1 includes a first shutter 41 provided so that the first shutter 41 can move to a position (B in FIG. 2 to be described later) where the first shutter 41 covers the surface of the first target 21 and to a position (C in FIG. 2 to be described later) where the first shutter 41 does not cover the surface of the first target 21. Similarly, the sputtering apparatus 1 includes a second shutter 42 for the second target 22.

The sputtering apparatus 1 includes a first shutter driving unit 43 and a second shutter driving unit 44. The first shutter driving unit 43 and the second shutter driving unit 44 respectively move the first shutter 41 and the second shutter 42 from covering positions (B) where the first shutter 41 and the second shutter 42 cover the surfaces of the first target 21 and the second target 22 to uncovering positions (C) where the first shutter 41 and the second shutter 42 do not cover the surfaces of the first target 21 and the second target 22, and respectively move the first shutter 41 and the second shutter 42 from the uncovering positions (C) to the covering positions (B).

Additionally, the sputtering apparatus 1 includes a shield panel 45 between the first target 21 and the second target 22. The shield panel 45 prevents particles (atoms or molecules) sputtered (flying out) from the second target 22 from adhering to the substrate 110 located at a position facing the first target 21. Similarly, the shield panel 45 prevents particles (atoms or molecules) sputtered (flying out) from the first target 21 from adhering to the substrate 110 located at a position facing the second target 22.

The sputtering apparatus 1 includes a first target heating/cooling unit 53 and a second target heating/cooling unit 54, and is capable of setting the temperature of the first target 21 and the second target 22 individually by means of heating with a heater or circulating coolant such as water in the first cathode 51 and the second cathode 52.

The sputtering apparatus 1 includes an exhaust unit 80 having a vacuum pump, such as a turbo molecular pump, a cryopump or an oil diffusion pump, and is capable of exhausting the chamber 10 through the exhaust pipe 14.

The sputtering apparatus 1 includes a controller 95 that controls operations of the first shutter driving unit 43, the second shutter driving unit 44, the first target heating/cooling unit 53, the second target heating/cooling unit 54, the substrate heating/cooling unit 61, the substrate holder rotating unit 62, the gas supply unit 70, the exhaust unit 80, the first power supply 91, the second power supply 92 and the third power supply 93, which are described above.

In the present exemplary embodiment, the inside of the chamber 10 is set so as to have a predetermined gas pressure by means of control of exhaust speed of the exhaust unit 80 by the exhaust speed adjusting valve 81 and control of the amount of gas supply by the gas supply unit 70.

FIG. 2 is a cross sectional view, taken along a line II-II, of the sputtering apparatus 1 shown in FIG. 1, and is a view of the bottom surface of the container 11 in a state where the targets (the first target 21 and the second target 22) are attached. FIG. 2 shows a state where the shutters (the first shutter 41 and the second shutter 42) are moved to the uncovering positions C (a shutter open state) at which the shutters do not cover the surfaces of the targets (the first target 21 and the second target 22). The shutters (the first shutter 41 and the second shutter 42) are allowed to move from the covering positions B (a shutter close state) at which the shutters cover the surfaces of the targets (the first target 21 and the second target 22) to the uncovering positions C (the shutter open state), and to move from the uncovering positions C (the shutter open state) to the covering positions B (the shutter close state), in the direction of an arrow E around an axis D.

The shutters (the first shutter 41 and the second shutter 42) has a function to separate the substrates 110 from the targets (the first target 21 and the second target 22) until the plasma discharge generated at the part of the targets (the first target 21 and the second target 22) is stabilized, so that no film is formed on the substrates 110.

The periphery of the targets (the first target 21 and the second target 22) are connected to the bottom surface of the container 11, and are covered with the shield members 15 that are provided so as to extend from the bottom surface of the container 11.

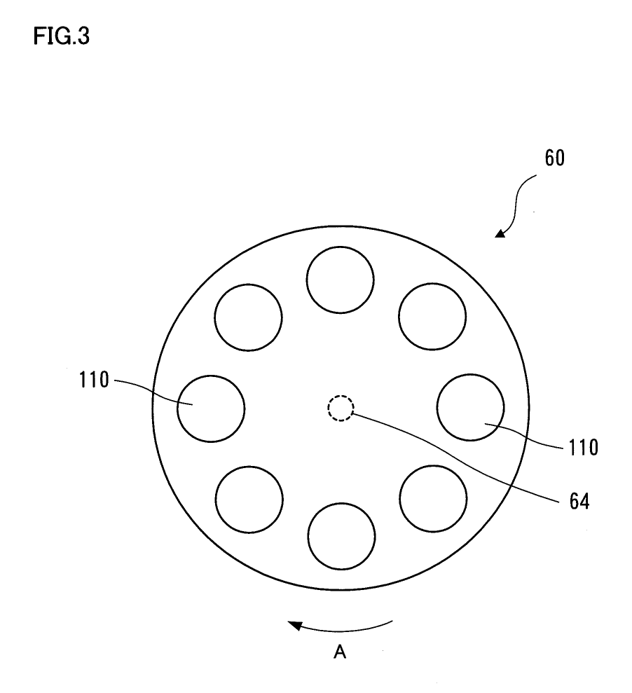

FIG. 3 is a surface view of the substrate holder 60 of the sputtering apparatus 1, seen from the targets (the first target 21 and the second target 22). In the present exemplary embodiment, the substrate holder 60 has a disk shape, and is capable of holding eight of the substrates 110 at positions near the outer circumference thereof. However, the number and positions of the substrates 110 to be held may appropriately be changed. The substrate holder 60 rotates around the rotation axis 64.

In order to form uniform films on the substrates 110, a positional relationship between the substrates 110 and the targets (the first target 21 and the second target 22) is preferably set so that the center of each substrate 110 passes over that of each target (the first target 21 or the second target 22). Additionally, in order to form uniform films on the substrates 110, the diameter of each target (the first target 21 or the second target 22) is preferably larger than that of each substrate 110.

In the present exemplary embodiment, the substrate holder 60 rotates in the direction of the arrow A. A mechanism to make the substrates 110 revolve may further be provided, and thereby the substrates 110 may be made to perform planetary rotation.

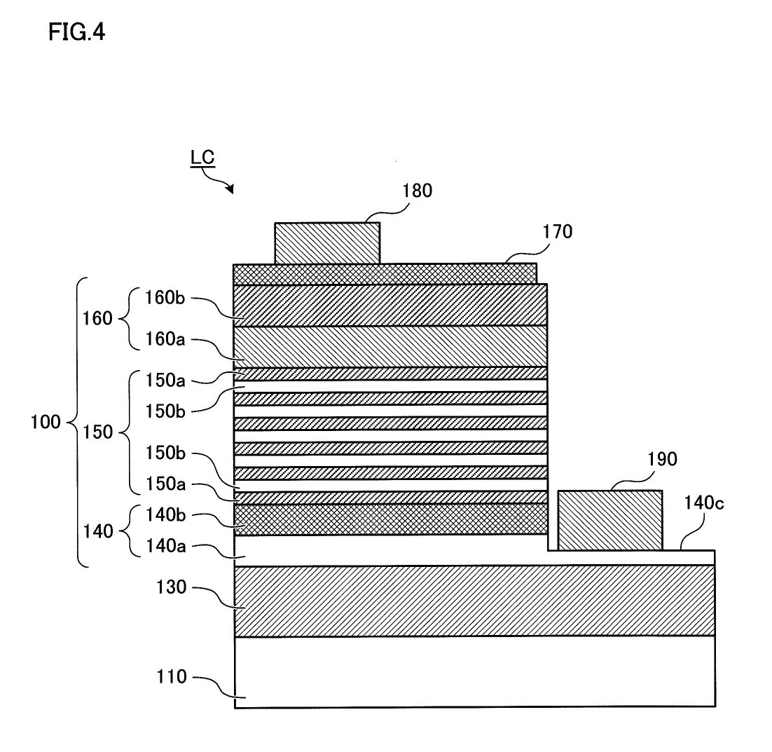

FIG. 4 shows a cross sectional structure of a semiconductor light emitter LC serving as an example of a semiconductor element manufactured by using the above-described sputtering apparatus 1. This semiconductor light emitter LC employs a compound semiconductor.

A compound semiconductor forming the semiconductor light emitter LC is not particularly limited, and a III-V compound semiconductor, a II-VI compound semiconductor, a IV-IV compound semiconductor and the like are listed as examples thereof. In the present exemplary embodiment, a III-V compound semiconductor is preferable, and a group III nitride compound semiconductor is particularly preferable. Hereinafter, a semiconductor light emitter LC having a group III nitride compound semiconductor will be described as an example. The semiconductor light emitter LC shown in FIG. 4 as an example is a semiconductor light emitter LC emitting blue light.

The semiconductor light emitter LC includes: the substrate 110; a base layer 130 formed on the substrate 110; an n-type semiconductor layer 140 formed on the base layer 130; a light-emitting layer 150 formed on the n-type semiconductor layer 140; a p-type semiconductor layer 160 formed on the light-emitting layer 150.

The n-type semiconductor layer 140 includes: an n-type contact layer 140a provided on the base layer 130 side; and an n-type clad layer 140b provided on the light-emitting layer 150 side. The light-emitting layer 150 has barrier layers 150a and well layers 150b alternately stacked, and has a structure in which two barrier layers 150a sandwiches one well layer 150b. Furthermore, the p-type semiconductor layer 160 includes: a p-type clad layer 160a provided on the light-emitting layer 150 side; and a p-type contact layer 160b provided at the uppermost layer. In the following description, the n-type semiconductor layer 140, the light-emitting layer 150 and the p-type semiconductor layer 160 will be collectively referred to as stacked semiconductor layer 100.

In the semiconductor light emitter LC, a transparent positive electrode 170 is stacked on the p-type contact layer 160b of the p-type semiconductor layer 160, and a positive electrode bonding pad 180 is further formed on the transparent positive electrode 170. Furthermore, a negative electrode bonding pad 190 is stacked on an exposed region 140c formed in the n-type contact layer 140a of the n-type semiconductor layer 140.

### (Substrate 110)

The substrate 110 is formed of a material different from a group III nitride compound semiconductor. On the substrate 110, group III nitride compound semiconductor crystals are epitaxially grown. Listed as examples of a material forming the substrate 110 are: sapphire, silicon carbide (SiC), gallium nitride (GaN), zinc oxide (ZnO), silicon, magnesium oxide, manganese oxide, zirconium oxide, zinc iron manganese oxide, magnesium aluminum oxide, zirconium boride, gallium oxide, indium oxide, lithium gallium oxide, lithium aluminum oxide, neodymium gallium oxide, lanthanum strontium aluminum tantalum oxide, strontium titanium oxide, titanium oxide, hafnium oxide, tungsten oxide, molybdenum oxide, glass such as fused quartz (quartz), and the like. Among these materials, sapphire and silicon carbide are preferable.

### (Base Layer 130)

As a material for the base layer 130, group III nitride including Ga (a GaN compound semiconductor) is used. In particular, InₓGa₁₋ₓN (where 0<x<1) (an InGaN compound semiconductor) is preferably used. The film thickness of the base layer 130 is 0.1 μm or more, preferably 0.5 μm or more, and more preferably 1 μm or more.

### (N-type Semiconductor Layer 140)

The N-Type Semiconductor Layer 140 is Formed of the N-Type Contact layer 140a and the n-type clad layer 140b.

As the n-type contact layer 140a, an InGaN compound semiconductor is used, similarly to the base layer 130. It is preferable that the InGaN compound semiconductor forming the base layer 130 have the same composition as the one forming the n-type contact layer 140a. The total film thickness of the base layer 130 and the n-type contact layer 140a is preferably set in a range of 0.1 μm to 20 μm, more preferably in a range of 0.5 μm to 15 μm, and further preferably in a range of 1 μm to 12 μm.

Meanwhile, the n-type clad layer 140b can be formed of AlGaN, GaN, InGaN or the like. Additionally, a structure obtained by heterojunction of structures of these compounds or a superlattice structure obtained by stacking structures of these compounds several times may be employed. If an InGaN compound semiconductor is employed as the n-type clad layer 140b, it is desirable that the band gap thereof be set larger than that of the InGaN compound semiconductor of the light-emitting layer 150. The film thickness of the n-type clad layer 140b is preferably in a range of 5 nm to 500 nm, and more preferably in a range of 5 nm to 100 nm.

### (Light-Emitting Layer 150)

The light-emitting layer 150 includes the barrier layers 150a formed of a GaN compound semiconductor and the well layers 150b formed of an InGaN compound semiconductor, these layers being alternately and repeatedly stacked. In addition, the light-emitting layer 150 is formed by multi-layering in such an order that the barrier layers 150a are arranged on the n-type semiconductor layer 140 side and the p-type semiconductor layer 160 side. In the present exemplary embodiment, the light-emitting layer 150 has the following configuration: six barrier layers 150a and five well layers 150b are alternately and repeatedly stacked; the barrier layers 150a are arranged at the uppermost layer and the lowermost layer of the light-emitting layer 150; and each well layer 150b is arranged between one barrier layer 150a and the next.

For the well layers 150b, In_{y}Ga_{1-y}N (where 0<y<1) or the like, as an InGaN compound semiconductor, can be used, for example.

For the barrier layers 150a, a GaN compound semiconductor, such as Al_{c}Ga_{1-c}N (where 0≦c≦0.3) or the like, having larger band gap energy than the well layers 150b can be preferably used.

It is preferable for each well layer 150b to have a film thickness enough to obtain quantum effect, although the film thickness is not particularly limited.

### (P-Type Semiconductor Layer 160)

The p-Type Semiconductor Layer 160 is Formed of the p-Type Clad Layer 160a and the p-type contact layer 160b. For the p-type clad layer 160a, Al_{d}Ga_{1-d}N (where 0<d≦0.4) is preferably taken as an example. The film thickness of the p-type clad layer 160a is preferably in 1 nm to 400 nm, and more preferably in 5 nm to 100 nm.

Meanwhile, for the p-type contact layer 160b, a GaN compound semiconductor layer including AlₑGa₁₋ₑN (where 0≦e<0.5) is taken as an example. The film thickness of the p-type contact layer 160b is preferably in 10 nm to 500 nm, and more preferably in 50 nm to 200 nm, although not particularly limited.

### (Transparent Positive Electrode 170)

Listed as examples of a material forming the transparent positive electrode 170 are: ITO (In₂O₃—SnO₂), AZO (ZnO—Al₂O₃), IZO (In₂O₃—ZnO), GZO (ZnO—Ga₂O₃), and the like, which are conventionally known materials. The structure of the transparent positive electrode 170 is not particularly limited, and a conventionally known structure can be employed. The transparent positive electrode 170 may be formed so as to cover almost all the surface of the p-type semiconductor layer 160, or may have a grid form or a tree-like form.

### (Positive Electrode Bonding Pad 180)

The positive electrode bonding pad 180 serving as an electrode formed on the transparent positive electrode 170 is formed of conventionally known materials, such as Au, Al, Ti, V, Cr, Mn, Co, Zn, Ge, Zr, Nb, Mo, Ru, Ta, Ni and Cu, for example. The structure of the positive electrode bonding pad 180 is not particularly limited, and a publicly known structure can be employed.

The thickness of the positive electrode bonding pad 180 is in a range of 100 nm to 2000 nm, for example, and preferably in a range of 300 nm to 1000 nm.

### (Negative Electrode Bonding Pad 190)

The negative electrode bonding pad 190 is formed so as to be in contact with the n-type contact layer 140a of the n-type semiconductor layer 140, in the stacked semiconductor layer 100 (the n-type semiconductor layer 140, the light-emitting layer 150 and the p-type semiconductor layer 160) further formed on the base layer 130 whose film is formed on the substrate 110. For this reason, when the negative electrode bonding pad 190 is formed, a part of the p-type semiconductor layer 160, the light-emitting layer 150 and the n-type semiconductor layer 140 is removed. Then, the exposed region 140c of the n-type contact layer 140a is formed, and the negative electrode bonding pad 190 is formed thereon.

The material of the negative electrode bonding pad 190 may have the same composition and structure as that of the positive electrode bonding pad 180. Negative electrodes having various compositions and structures are well known. These well-known negative electrodes can be used without any limitations, and can be provided by a conventional means well known in the art.

### (Manufacturing Method of Semiconductor Light Emitter Lc)

First, the substrates 110 made of sapphire and having a predetermined diameter and a predetermined thickness are set in the sputtering apparatus 1 shown in FIG. 1. Then, the base layer 130 formed of a group III nitride compound semiconductor is formed on the substrates 110 by the sputtering apparatus 1.

Subsequently, the n-type contact layer 140a is formed by an unillustrated MOCVD apparatus on the substrates 110, on which the base layer 130 is formed. The n-type clad layer 140b is formed on the n-type contact layer 140a. Furthermore, the light-emitting layer 150, namely, the barrier layers 150a and the well layers 150b are alternately formed on the n-type clad layer 140b. The p-type clad layer 160a is formed on the light-emitting layer 150, and the p-type contact layer 160b is formed on the p-type clad layer 160a.

Furthermore, the transparent positive electrode 170 is stacked on the p-type contact layer 160b, and the positive electrode bonding pad 180 is formed thereon. Additionally, the exposed region 140c is formed in the n-type contact layer 140a by means of etching or the like, and the negative electrode bonding pad 190 is provided in this exposed region 140c.

After that, the surface of the substrate 110 opposite to the surface on which the base layer 130 is formed is ground and abraded until the substrate 110 has a predetermined thickness.

The wafer in which the thickness of the substrate 110 is adjusted is then cut into a square with sides of 350 μm, for example, and thereby the semiconductor light emitter LC is obtained.

In the semiconductor light emitter LC using the substrate 110 made of sapphire, an intermediate layer formed of MN or AlGaN may be provided between the substrate 110 made of sapphire and the base layer 130 in order to reduce a difference between the lattice constants. However, in the present exemplary embodiment, the base layer 130 having excellent crystallinity is allowed to be formed directly on the substrate 110, and thus no intermediate layer is provided.

Now, a description is given of the operations of the sputtering apparatus 1 in the above-described manufacturing method of the semiconductor light emitter LC.

### (Operations of Sputtering Apparatus 1)

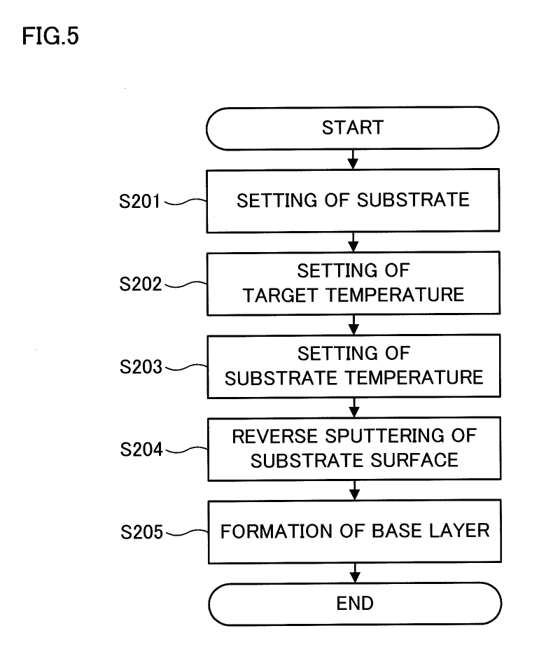

FIG. 5 is a flowchart for explaining a method to form the base layer 130 on the substrates 110. Hereinafter, a description will be given of the flowchart shown in FIG. 5 for forming the base layer 130 on the substrates 110, with reference to FIG. 1.

First, plate-shaped metallic indium (In), serving as an example of a group III element, is attached to the target holder of the first cathode 51 as the first target 21. Plate-shaped metallic gallium (Ga), serving as an example of a group III element, is attached to the target holder of the second cathode 52 as the second target 22. Since the melting point of metallic gallium (Ga) is 29.8 degrees C., it is easy to melt by an increase in temperature during sputtering. Thus, in order to prevent a discharge due to melting, it is preferable that metallic gallium (Ga) be put into a petri-dish-like case made of copper (Cu) or the like, and be placed in the target holder of the second cathode 52.

Then, the lid portion 12 of the sputtering apparatus 1 is opened, and eight substrates 110 that are made of sapphire and have a predetermined diameter and a predetermined thickness are placed on the substrate holder 60 (Step 201). On this occasion, each substrate 110 is placed so that the surface on which the base layer 130 is formed faces outside of the substrate holder 60. As the substrates 110 made of sapphire, a substrate whose surface is provided with an offset angle of 0.35 degrees with respect to the C-plane of a sapphire crystal may be used, for example.

After that, the lid portion 12 is closed, so that the lid portion 12 is brought into close contact with the container 11.

Then, the chamber 10 of the sputtering apparatus 1 is exhausted by the exhaust unit 80, until the chamber 10 has a predetermined degree of vacuum.

Rotation of the substrate holder 60 is started by the substrate holder rotating unit 62. Then, the substrate holder 60 rotates in the direction of the arrow A shown in FIG. 1. The rotation speed is 5 rpm or more, for example.

The first target 21 and the second target 22 are set at a predetermined temperature by the first target heating/cooling unit 53 and the second target heating/cooling unit 54, respectively (Step 202). The first target 21 and the second target 22 may be set at temperatures different from each other. For the temperature of the targets (the first target 21 and the second target 22), 20 degrees C., 40 degrees C. or the like may be used, for example. The second target 22 of metallic gallium (Ga) is maintained in the solid state at 20 degrees C., and becomes in the liquid state at 40 degrees C.

Furthermore, the substrates 110 are set at a predetermined temperature by the substrate heating/cooling unit 61 (Step 203). For the temperature of the substrates 110, a range between 150 degrees C. and 800 degrees C. both inclusive, preferably a range between 180 degrees C. and 700 degrees C. both inclusive, and further preferably a range between 200 degrees C. and 600 degrees C. both inclusive may be used, for example.

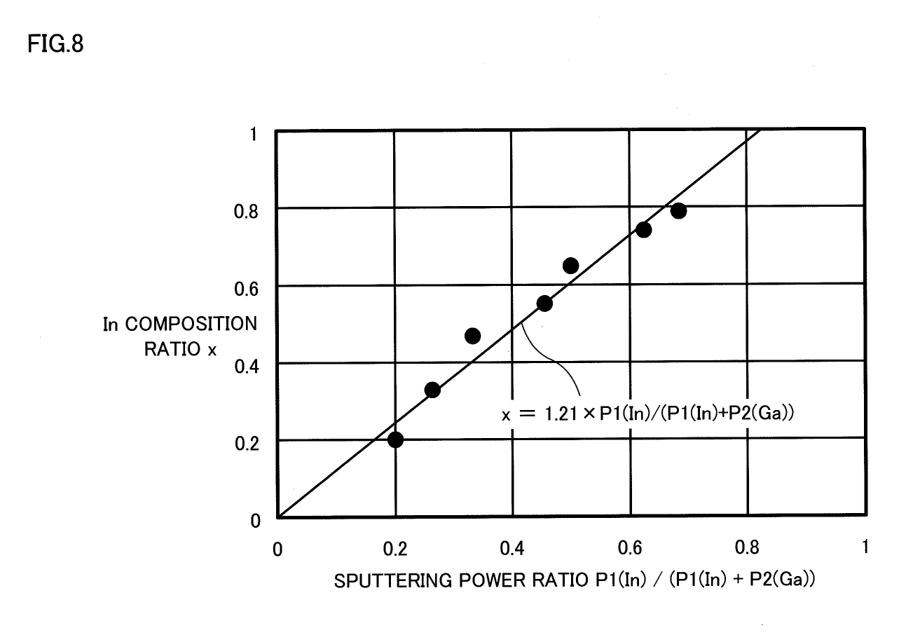

If the substrate temperature exceeds 800 degrees C., then much In sublimes from the compound semiconductor made of InₓGa₁₋ₓN (where 0<x<1) whose film is formed by sputtering, or In easily deposits in the formed film. This prevents formation of a compound semiconductor having a predetermined In composition ratio x (in FIG. 8, x indicates a ratio of the number of In atoms to the total number of Ga and In atoms, and is in a range of 0 to 1). Meanwhile, if the substrate temperature is lower than 150 degrees C., a film having good crystallinity cannot be obtained.

In the present exemplary embodiment, a compound semiconductor formed of InₓGa₁₋ₓN (where 0<x<1) including the In composition ratio x of 0.7 or more may use, as the temperature of the substrates 110, a range between 150 degrees C. and 400 degrees C. both inclusive, preferably a range between 180 degrees C. and 350 degrees C. both inclusive, and further preferably a range between 200 degrees C. and 300 degrees C. both inclusive.

If the substrate temperature exceeds 400 degrees C., then In sublimes from the compound semiconductor made of InₓGa₁₋ₓN (where 0<x<1) whose film is formed by sputtering, or In easily deposits in the formed film. This prevents formation of a compound semiconductor having a predetermined In composition ratio x. Meanwhile, if the substrate temperature is lower than 150 degrees C., a film having good crystallinity cannot be obtained.

Furthermore, in the present exemplary embodiment, a compound semiconductor formed of InₓGa₁₋ₓN (where 0<x<1) whose In composition ratio x is smaller than 0.7 may use, as the temperature of the substrates 110, a range between 150 degrees C. and 800 degrees C. both inclusive, preferably a range between 180 degrees C. and 700 degrees C. both inclusive, and further preferably a range between 200 degrees C. and 600 degrees C. both inclusive.

If the substrate temperature exceeds 800 degrees C., then much In sublimes from the compound semiconductor made of InₓGa₁₋ₓN (where 0<x<1) whose film is formed by sputtering, or In easily deposits in the formed film. This prevents formation of a compound semiconductor having a predetermined In composition ratio x. Meanwhile, if the substrate temperature is lower than 150 degrees C., a film having good crystallinity cannot be obtained.

Moreover, in a case of a semiconductor photo detector, the In composition ratio x is preferably not less than 0.3 and less than 0.7, and the temperature of the substrates 110 is preferably more than 400 degrees C. and not more than 800 degrees C.

The temperatures of the targets (the first target 21 and the second target 22) and the substrates 110 are measured by a temperature measurement unit such as a thermocouple attached near the targets (the first target 21 and the second target 22) and to the substrate holder 60. Each of the temperatures are controlled in a predetermined temperature range by the first target heating/cooling unit 53, the second target heating/cooling unit 54 and the substrate heating/cooling unit 61.

A predetermined flow amount of nitrogen is supplied into the chamber 10 by the gas supply unit 70. The exhaust speed is adjusted by the exhaust speed adjusting valve 81, and thereby the inside of the chamber 10 is adjusted so as to have a predetermined gas pressure.

Next, in order to remove absorbed gas, stain and the like on the surfaces of the substrates 110, high frequency power is supplied to the substrate holder 60 by the third power supply 93, and the surfaces of the substrates 110 on the substrate holder 60 is subjected to sputtering (reverse sputtering) for a predetermined time period (Step 204).

The reverse sputtering is preferably performed only with nitrogen, without mixing argon, which has a large mass, in order to prevent the surfaces of the substrates 110 from being roughed.

Next, a predetermined flow amount of argon and nitrogen is supplied into the chamber 10 by the gas supply unit 70. The exhaust speed is adjusted by the exhaust speed adjusting valve 81, and thereby the inside of the chamber 10 is adjusted so as to have a predetermined gas pressure. For example, the flow amount of argon may be set at 2 sccm, and that of nitrogen may be set at 50 sccm to 100 sccm. The flow amount of nitrogen may not be the same as the one in the case of the above-described reverse sputtering. Since nitrogen is a reaction gas to form a group III nitride compound semiconductor, nitrogen cannot be set at 0%, but may be set at 100%.

Then, high frequency power or direct current power is supplied from the first power supply 91 and the second power supply 92 to the first target 21 and the second target 22, respectively, while both of the first shutter 41 and the second shutter 42 are in the shutter close state. Thereby, plasma discharge is generated around the surfaces of the first target 21 and the second target 22.

When the plasma discharge is stabilized, the first shutter 41 and the second shutter 42 are moved to the positions at which the shutters are opened, to form the base layer 130 on the surfaces of the substrates 110 (Step 205).

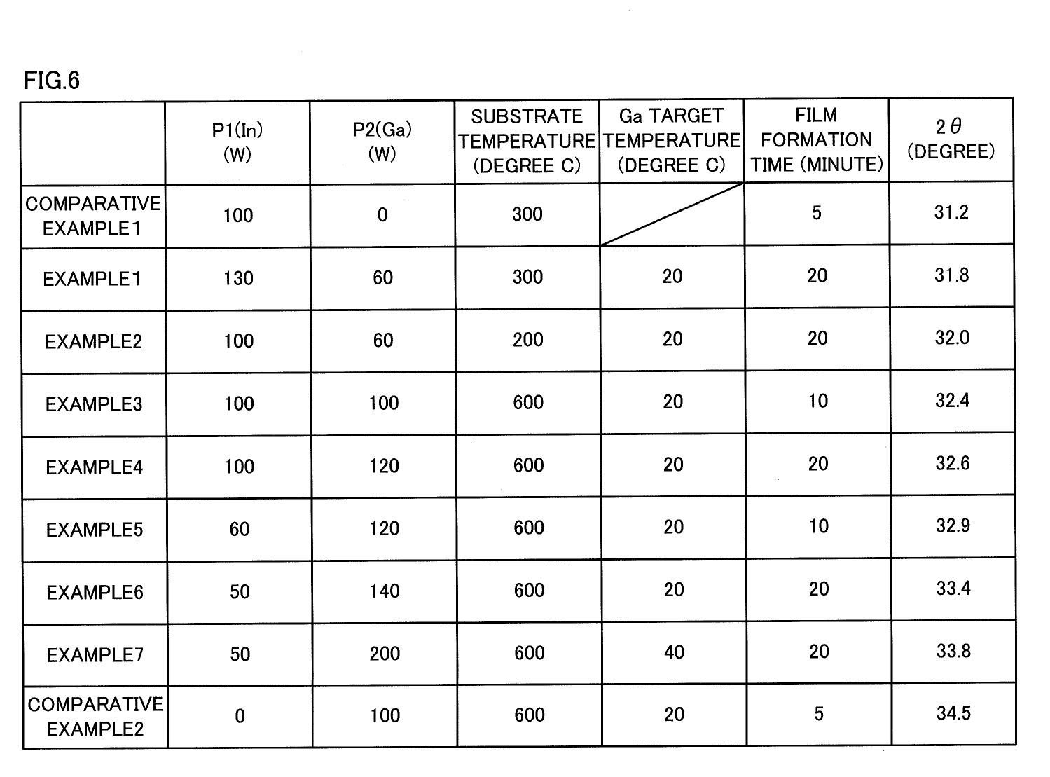

In the present exemplary embodiment, the substrates 110 on the rotating substrate holder 60 alternately pass the positions respectively facing the first target 21 and the second target 22. Thus, particles coming from the first target 21 and particles coming from the second target 22 are alternately stacked, and thereby a film in which these particles are mixed is formed. The ratio between the particles coming from the first target 21 and the particles coming from the second target 22 is allowed to be adjusted by means of power supplied to the respective targets. That is, the composition ratio of a film formed of a group III nitride compound semiconductor is determined by first sputtering power P1 (see FIG. 6 to be described later) supplied to the first target 21 and second sputtering power P2 (see FIG. 6 to be described later) supplied to the second target 22.

When the base layer 130 having a predetermined film thickness is formed, the first shutter 41 and the second shutter 42 are moved to the positions at which the shutters are closed, and then formation of the film is finished. The film thickness of the base layer 130 may be controlled according to film formation time (a time period from shutter opening to shutter closing), on the basis of a relationship between a film thickness and formation time that are obtained when film formation is performed in advance.

After that, the plasma discharge is stopped, and the gas is exhausted from the chamber 10. Next, the process waits until the temperature of the substrates 110 and that of the targets (the first target 21 and the second target 22) become in a state where the inside of the chamber 10 is ready to recover the atmosphere pressure. Return to the atmosphere pressure is performed by, for example, supply of nitrogen into the chamber 10 by the gas supply unit 70. Then, the lid portion 12 is opened, and the substrates 110 on each of which the base layer 130 is formed are taken out.

As described above, the base layer 130 that is group III nitride is formed on each substrate 110 by the sputtering apparatus 1.

Then, the semiconductor light emitter LC shown in FIG. 4 is manufactured through the above-described manufacturing method of the semiconductor light emitter LC.

In the above-described manufacturing method of the semiconductor light emitter LC, the base layer 130 is formed on each substrate 110 by using the sputtering apparatus 1. The n-type semiconductor layer 140, the light-emitting layer 150 and the p-type semiconductor layer 160, which are subsequent to the base layer 130, may also be formed through a procedure similar to the one described above, by using the sputtering apparatus 1.

Meanwhile, the present invention may include a semiconductor photo detector (a solar battery (not shown)) as another example of a semiconductor element manufactured by using the above-described sputtering apparatus 1. The semiconductor photo detector may employ a compound semiconductor as an example.

A compound semiconductor forming a semiconductor photo detector is not particularly limited, and a III-V compound semiconductor, a II-VI compound semiconductor, a IV-IV compound semiconductor and the like are listed as examples thereof. In the present exemplary embodiment, a III-V compound semiconductor is preferable, and a group III nitride compound semiconductor is particularly preferable. As an example of a semiconductor photo detector having a group III nitride compound semiconductor, a cross sectional structure and a plan view described in Japanese Patent Application Laid Open Publication No. 2008-235878 (for example, FIGS. 1 to 4) may be employed.

Also in a manufacturing method of a semiconductor photo detector, the substrates 110 (for example, sapphire) having a predetermined diameter and a predetermined thickness are set in the sputtering apparatus 1 shown in FIG. 1. Then, in the sputtering apparatus 1, films made of a group III nitride compound semiconductor are formed on the substrates 110. Such films made of a group III nitride compound semiconductor may be InₓGa₁₋ₓN (where 0<x<1).

As described above, also in a manufacturing method of a semiconductor photo detector, a method described in the above manufacturing method of the semiconductor light emitter LC may be preferably employed.

### EXAMPLES

Next, a description will be given of examples of the present invention. However, the present invention is not limited to the examples.

The inventor formed films (the base layer 130) of a group III nitride compound semiconductor on the substrates 110 made of sapphire, by using the sputtering apparatus 1 shown in FIG. 1, according to the flowchart shown in FIG. 5. The inventor then examined crystallinity and composition of the films. Crystallinity of the films was evaluated by means of X-ray diffraction (XD) using a Kα ray of Cu (CuKα) (whose wavelength is 0.15418 nm) and of a scanning electron microscope (SEM). Composition ratios of the films including In were evaluated by means of wet analysis or X-ray diffraction.

### Examples 1 to 7 and Comparative Examples 1 and 2

FIG. 6 is a table showing a relationship between various manufacturing conditions and evaluation results for examples 1 to 7 and comparative examples 1 and 2. In FIG. 6, data is arranged in descending order of the first sputtering power P1 (P1(In) in FIG. 6) supplied to the first target 21 (an In target) of metallic indium (In) and in ascending order of the second sputtering power P2 (P2(Ga) in FIG. 6) supplied to the second target 22 (a Ga target) of metallic gallium (Ga). For this reason, the examples 1 to 7 are shown between the comparative examples 1 and 2.

Substrates each having a diameter of 2 inches (about 50 mm) were used as the substrates 110 made of sapphire, and targets each having a diameter of 4 inches (about 100 mm) were used as the In target and the Ga target.

In FIG. 6, the first sputtering power P1 supplied to the In target, the second sputtering power P2 supplied to the Ga target, the temperature of the substrates 110 (substrate temperature), the temperature of the Ga target and the film formation time are written as the manufacturing conditions. Additionally, in FIG. 6, angles (2θ) of the peaks of the X-ray diffraction are shown as the evaluation results.

In the examples 1 to 7, films are formed with different ratios of the first sputtering power P1 supplied to the In target (the first target 21) to the second sputtering power P2 supplied to the Ga target (the second target 22). The rotation speed of the substrate holder 60 is set at 5 rpm.

In the comparative example 1, films are formed by using only the In target. Here, rotation of the substrate holder 60 is stopped, and the films are formed while the substrates 110 are made to face the In target. Meanwhile, in the comparative example 2, films are formed by using only the Ga target. Also here, rotation of the substrate holder 60 is stopped, and the films are formed while the substrates 110 are made to face the Ga target.

The substrate temperature is set at 300 degrees C. in the comparative example 1 and the example 1, at 200 degrees C. in the example 2, and at 600 degrees C. in the examples 3 to 7 and the comparative example 2. The reason why the substrate temperature is lowered in the comparative example 1 and the examples 1 and 2 is because In is easy to deposit if the density of In is high and if the substrate temperature is high, like 600 degrees C., for example. However, if the substrate temperature is lowered to the room temperature, films having good crystallinity cannot be obtained.

The temperature of the Ga target is set at 20 degrees C., except for 40 degrees C. of the example 7. The Ga target is maintained in the solid state at 20 degrees C., and becomes in the liquid state at 40 degrees C. Note that the result has no difference irrespective of whether the Ga target is in the solid state or in the liquid state.

The film formation time of the examples 1 to 7 is set at 10 minutes or 20 minutes. The thickness of the formed films is about 10 nm for 10 minutes of the film formation time, and is about 20 nm for 20 minutes of the film formation time. Meanwhile, the film formation time of the comparative examples 1 and 2 is set at 5 minutes, because the substrate holder 60 is not rotated.

The angles 2θ vary in a direction increasing from 31.2 degrees to 34.5 degrees, in order of the comparative example 1, the examples 1 to 7 and the comparative example 2.

In the comparative example 1, the films are formed by use of only the In target, and thus films of InN are formed. The angle 2θ of the comparative example 1 is 31.2 degrees. The interplanar spacing is calculated at 0.29 nm from this value.

InN has a wurtzite structure of the hexagonal system (a=0.548 nm, c=0.576 nm). The hexagonal system has a lattice plane in the middle of the c-axis. The above-described interplanar spacing of 0.29 nm is substantially equal to 0.288 nm, which is ½ of the lattice spacing (c) in the direction of the c-axis of InN. That is, the films of InN in the comparative example 1 are those oriented in the direction of the c-axis of the InN crystal.

Similarly, in the comparative example 2, the films are formed by use of only the Ga target, and thus films of GaN are formed. The angle 2θ of the comparative example 2 is 34.5 degrees. The interplanar spacing is calculated at 0.26 nm from this value. This 0.26 nm is equal to 0.2588 nm, which is ½ of the lattice spacing (c) in the direction of the c-axis of the GaN crystal (a=0.3186 nm, c=0.5176 nm) having a wurtzite structure similar to that of InN. That is, the films of GaN in the comparative example 2 are those oriented in the direction of the c-axis of the GaN crystal.

In contrast, as shown in FIG. 6, in the examples 1 to 7, the films are formed by using the In target and the Ga target. Additionally, the peak of the X-ray diffraction for each film of the examples 1 to 7 is placed between the peak of the InN film of the comparative example 1 and that of the GaN film of the comparative example 2. Thus, the films of the examples 1 to 7 are those of InₓGa₁₋ₓN (where 0<x<1) having the In composition ratios x different from each other. That is, this implies that films made of InN and GaN are formed. Additionally, these films are also oriented in the direction of the c-axis of the respective crystals.

This shows that films of a group III nitride compound semiconductor having different composition ratios and oriented in the direction of the c-axis can be formed if film formation is performed by varying the ratio of the first sputtering power P1 supplied to the In target to the second sputtering power P2 supplied to the Ga target.

That is, each formed film is a compound (InₓGa₁₋ₓN), although, here, particles (InN) from the first target 21 and particles (GaN) from the second target 22 are alternately stacked onto the substrates 110 by using multi-targets of the first target 21 (the In target) and the second target 22 (the Ga target).

Additionally, the film formation is performed by using metallic materials (In of the first target 21 and Ga of the second target 22) as target materials, and nitrogen as a (sputter) gas, which shows that nitride of these metallic materials is formed.

Here, particles from the first target 21 (the In target) and the second target 22 (the Ga target) are alternately stacked onto the substrates 110 by rotating the substrate holder 60. However, the first target 21 (the In target) and the second target 22 (the Ga target) may be arranged adjacently to the substrates 110, and particles from the two targets (the In target and the Ga target) may be deposited onto the substrates 110 at the same time (co-sputtering).

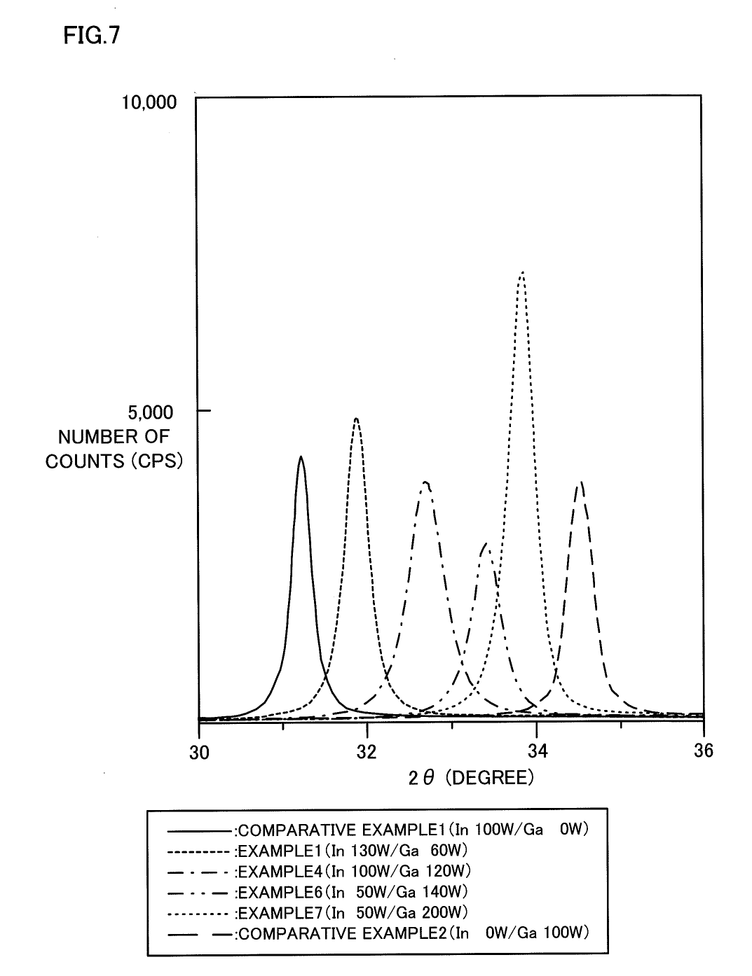

FIG. 7 is a graph showing peaks of the X-ray diffraction for the examples 1, 4, 6 and 7 and the comparative examples 1 and 2. All of the peaks of the X-ray diffraction have extremely narrow half widths of about 0.3 degrees. This shows that each film of the examples 1, 4, 6 and 7 and the comparative examples 1 and 2 is a film close to a single crystal. The same is true for the examples 2, 3 and 5, although not shown in FIG. 7.

According to observation with a scanning electron microscope (SEM), it is found that crystal films including columnar crystals are formed in the comparative example 1 and the examples 1 to 7.

FIG. 8 is a graph showing a relationship between the In composition ratio x and a sputtering power ratio P1/(P1+P2) (in FIG. 8, the ratio is P1(In)/(P1(In)+P2(Ga)), and also below, this notation will be used) for the examples 1 to 7. In FIG. 8, the horizontal axis is the sputtering power ratio P1(In)/(P1(In)+P2(Ga)), while the vertical axis is the In composition ratio x.

The sputtering power ratio P1(In)/(P1(In)+P2(Ga)) is obtained from the first sputtering power P1 supplied to the In target and the second sputtering power P2 supplied to the Ga target.

The In composition ratio x of InₓGa₁₋ₓN is obtained from 2θ in the examples 1 to 7.

The relationship between the In composition ratio x and the sputtering power ratio P1(In)/(P1(In)+P2(Ga)) in the examples 1 to 7 can be represented with one straight line passing the origin. This straight line is approximated by

x=1.21×P1(In)/(P1(In)+P2(Ga)).

This implies that the In composition ratio x can be arbitrarily set by adjusting the first sputtering power P1 supplied to the In target and the second sputtering power P2 supplied to the Ga target, on the basis of the above formula.

Note that films of InₓGa₁₋ₓN having a similar In composition ratio x may be formed as long as the sputtering power ratio is same as the one described above, even if a different sputtering apparatus is used.

### Comparative Example 3

Films (the base layer 130) of a group III nitride compound semiconductor were formed on the substrates 110 made of sapphire, by performing similarly to the example 1, except for removing the shield panel 45 included between the first target 21 and the second target 22 from the sputtering apparatus 1 shown in FIG. 1. Crystallinity and composition of the films were examined. Then, the In composition ratio x was 0.66. The In composition ratio x in the films of the formed compound semiconductor was lower than that in the example 1.

### Comparative Example 4

Films (the base layer 130) of a group III nitride compound semiconductor were formed on the substrates 110 made of sapphire, by performing similarly to the example 2, except for removing the shield panel 45 included between the first target 21 and the second target 22 from the sputtering apparatus 1 shown in FIG. 1. Crystallinity and composition of the films were examined. Then, the In composition ratio x was 0.59. The In composition ratio x in the films of the formed compound semiconductor was lower than that in the example 1.

As described above, according to the results of the comparative examples 3 and 4, when the shield panel 45 included between the first target 21 and the second target 22 is removed, the relationship described in FIG. 8 is not satisfied, and the compound semiconductor films of InₓGa₁₋ₓN (where 0<x<1) having a predetermined In composition ratio x cannot be manufactured.

Although the semiconductor light emitter LC has been mainly described as an example of a semiconductor element in the present exemplary embodiment, a semiconductor photo detector described in Japanese Patent Application Laid Open Publication No. 2008-235878 and having various In composition ratios x (in the range of 0<x<1 for compound semiconductor films formed of InₓGa₁₋ₓN) may also be manufactured. In particular, in the present exemplary embodiment, compound semiconductor films can be formed on arbitrary heterogeneous substrates so as to have a large area and with low cost, even in a range where the composition ratio x of indium (In) includes 0.7 or more.

Furthermore, the present invention can be applied to an electronic device.

### REFERENCE SIGNS LIST

1 . . . sputtering apparatus
10 . . . chamber
11 . . . container
12 . . . lid portion
13 . . . supply pipe
14 . . . exhaust pipe
21 . . . first target
22 . . . second target
41 . . . first shutter
42 . . . second shutter
43 . . . first shutter driving unit
44 . . . second shutter driving unit
51 . . . first cathode
52 . . . second cathode
53 . . . first target heating/cooling unit
54 . . . second target heating/cooling unit
60 . . . substrate holder
61 . . . substrate heating/cooling unit
62 . . . substrate holder rotating unit
64 . . . rotation axis
65 . . . heater
70 . . . gas supply unit
71 . . . Ar source
72 . . . N₂ source
80 . . . exhaust unit
81 . . . exhaust speed adjusting valve
91 . . . first power supply
92 . . . second power supply
93 . . . third power supply
95 . . . controller
100 . . . stacked semiconductor layer
110 . . . substrate
130 . . . base layer
140 . . . n-type semiconductor layer
150 . . . light-emitting layer
160 . . . p-type semiconductor layer
170 . . . transparent positive electrode
180 . . . positive electrode bonding pad
190 . . . negative electrode bonding pad
LC . . . semiconductor light emitter
P1 . . . first sputtering power
P2 . . . second sputtering power

1. A manufacturing method of a semiconductor element formed by multi-layering on a substrate so as to include an n-type semiconductor and a p-type semiconductor,
the method comprising a process of sputtering, with a gas including a group V element, at least two targets made of group III elements that are different from each other, thereby to form a film of a III-V compound semiconductor on the substrate.

2. The manufacturing method of a semiconductor element according to claim 1, wherein a shield panel is included between the at least two targets made of the group III elements that are different from each other.

3. The manufacturing method of a semiconductor element according to claim 1, wherein a composition ratio of the compound semiconductor is set by sputtering power supplied to each of the at least two targets made of the group III elements.

4. The manufacturing method of a semiconductor element according to claim 1, wherein the substrate is alternately located at each of positions respectively facing the at least two targets, and thereby the film of the compound semiconductor is formed.

5. The manufacturing method of a semiconductor element according to claim 1, wherein the group III elements are indium (In) and gallium (Ga), the group V element is nitrogen (N), and the compound semiconductor is InₓGa₁₋ₓN (where 0<x<1).

6. The manufacturing method of a semiconductor element according to claim 5, wherein the composition ratio x of indium (In) in the compound semiconductor is set, by sputtering power P1 supplied to one of the targets made of the indium (In) and sputtering power P2 supplied to one of the targets made of the gallium (Ga), as follows
x=1.21×P1/(P1+P2).

7. The manufacturing method of a semiconductor element according to claim 5, wherein the composition ratio x of indium (In) in the compound semiconductor is in a range of not less than 0.7, and substrate temperature is set to be not less than 150 degrees C. and not more than 400 degrees C.

8. The manufacturing method of a semiconductor element according to claim 5, wherein the composition ratio x of indium (In) in the compound semiconductor is in a range of not less than 0.3 and less than 0.7, and substrate temperature is set to be more than 400 degrees C. and not more than 800 degrees C.

9. The manufacturing method of a semiconductor element according to claim 1, wherein the substrate is formed of any one of sapphire, silicon carbide (SiC), gallium nitride (GaN), zinc oxide (ZnO), quartz and amorphous solid (glass).

10. The manufacturing method of a semiconductor element according to claim 1, wherein the semiconductor element is any one of a semiconductor light emitter and a semiconductor photo detector.
